(19) United States
(12) Patent Application Publication
(10) Pub. No.: US 2003/0132775 A1
(43) Pub. Date: Jul. 17, 2003

(54) Test apparatus for an oscillation circuit incorporated in IC

(75) Inventors: Satoshi Yamanaka, Tokyo (JP); Mutsumi Terai, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/184,881

(22) Filed: Jul. 1, 2002

(30) Foreign Application Priority Data
Jan. 15, 2002 (JP) 2002-005925

(51) Int. Cl. G01R 31/26

(52) U.S. Cl. 324/765

(57) ABSTRACT

A test apparatus includes, a plurality of band pass filters, each having a different center frequency, to which an oscillation signal of the PLL circuit is supplied. Further, a counter corresponding to each band pass filter counts the signal output from the band pass filter. The result of the counting by the counters is supplied to a test circuit. The test circuit detects defectiveness of the PLL circuit based on received results of the counting.

### FIELD OF THE INVENTION

The present invention relates to a test apparatus for oscillation circuit incorporated in an integrated circuit (IC) which conducts a jitter test on the oscillation circuits incorporated in the IC.

### BACKGROUND OF THE INVENTION

The IC's, such as the one-chip microcomputers, often have a phase locked loop (PLL) circuit or an oscillation buffer as an oscillation circuit. In the one-chip microcomputer incorporating the PLL, a clock signal supplied from an external oscillation circuit or an internal reference oscillator is input to the PLL circuit. The PLL circuit conducts phase synchronization between the input clock signal and an internally generated clock signal. In addition, the PLL circuit outputs the clock signal subjected to phase synchronization as it is. Alternatively the PLL circuit multiplies the frequency by n to generate a fast clock signal, and employs the fast clock signal as a system clock signal to be used within the microcomputer.

In inspecting a fast clock signal output from the PLL of such an IC incorporating the PLL, a technique shown in FIG. 11 is conventionally adopted.

With reference to FIG. 11, a tester incorporates a counter, which counts a fast clock signal output from a PLL. By counting the fast clock signal in a predetermined interval in the tester, the frequency of the fast clock signal output from the PLL is measured. The PLL is judged to be good or not by determining whether the measured frequency coincides with a desired frequency.

FIG. 12 shows waveforms of the fast clock signal output from the PLL. If the PLL is good, the waveform of the fast clock signal becomes the upper waveform in the figure. If the PLL is bad with poor jitter characteristics, temporal shaking (jitter) occurs in the fast clock signal as shown by the lower waveform in the figure.

However, the simple count test as in the conventional technique has a problem that an inspection of jitter cannot be conducted and a PLL having large jitter cannot be sorted.

### SUMMARY OF THE INVENTION

It is an object of this invention to provide a test apparatus for oscillation circuit incorporated in an IC which makes it possible to test jitter characteristics of the oscillation circuits.

The test apparatus for conducting a jitter test on an oscillation circuit incorporated in an integrated circuit according to one aspect of the present invention comprises a plurality of band pass filters each of which receives an oscillation signal output by the oscillation circuit, wherein each of the band pass filters has an oscillation frequency band of the oscillation circuit and a plurality of different frequencies located near the oscillation frequency band of the oscillation circuit as pass band center frequencies, a plurality of counters, one counter corresponding to one of the band pass filters, wherein the counter counts a signal output from the corresponding band pass filter, and a test circuit which receives the result of the counting by the counters and detects defectiveness of the oscillation circuit based on the received result of the counting.

The test apparatus for conducting a jitter test on an oscillation circuit incorporated in an integrated circuit according to another aspect of the present invention comprises a frequency divider which receives an oscillation signal output by the oscillation circuit and conducts frequency division on the oscillation signal to produce a frequency-divided oscillation signal, a plurality of band pass filters each of which receives the frequency-divided oscillation signal output by the frequency divider, wherein each of the band pass filters has an oscillation frequency band of the oscillation circuit subjected to frequency division and a plurality of different frequencies located near the oscillation frequency band of the oscillation circuit subjected to frequency division as pass band center frequencies, a plurality of counters, one counter corresponding to one of the band pass filters, wherein the counter counts a signal output from the corresponding band pass filter, and a test circuit which receives the result of the counting by the counters and detects defectiveness of the oscillation circuit based on the received result of the counting.

Other objects and features of this invention will become apparent from the following description with reference to the accompanying drawings.

### BRIEF DESCRIPTION OF THE DRAWINGS

FIG. 1 is a block diagram which shows a configuration of the first embodiment of the test apparatus for oscillation circuit incorporated in an IC according to the present invention,

FIG. 2A shows a waveform when outputs of a good PLL circuit is measured by using a spectrum analyzer, and FIG. 2B shows a waveform when outputs of a defective PLL circuit is measured by using the spectrum analyzer,

FIG. 3A shows count-frequency relations obtained when outputs of a good PLL circuit is measured by using a counter via a plurality of BPF's, and FIG. 3B shows count-frequency relations obtained when outputs of a defective PLL circuit is measured by using a counter via a plurality of BPF's,

FIG. 4 is a block diagram which shows a configuration of the second embodiment of the test apparatus for oscillation circuit incorporated in an IC according to the present invention,

FIG. 5 is a block diagram which shows a configuration of the third embodiment of the test apparatus for oscillation circuit incorporated in an IC according to the present invention,

FIG. 6 is a block diagram which shows a configuration of the fourth embodiment of the test apparatus for oscillation circuit incorporated in an IC according to the present invention,

FIG. 7 is a block diagram which shows a configuration of the fifth embodiment of the test apparatus for oscillation circuit incorporated in an IC according to the present invention,

FIG. 8 is a block diagram which shows a configuration of the sixth embodiment of the test apparatus for oscillation circuit incorporated in an IC according to the present invention,

FIG. 9 is a block diagram which shows a configuration of the seventh embodiment of the test apparatus for oscillation circuit incorporated in an IC according to the present invention,

FIG. 10 is a block diagram which shows a configuration of the eighth embodiment of the test apparatus for oscillation circuit incorporated in an IC according to the present invention,

FIG. 11 is a diagram which shows a conventional art, and

FIG. 12 is a diagram which shows waveforms of an oscillation signal with jitter and an oscillation signal without jitter.

### DETAILED DESCRIPTIONS

Embodiments of the test apparatus according to the present invention will be explained in detail below with reference to the accompanying drawings.

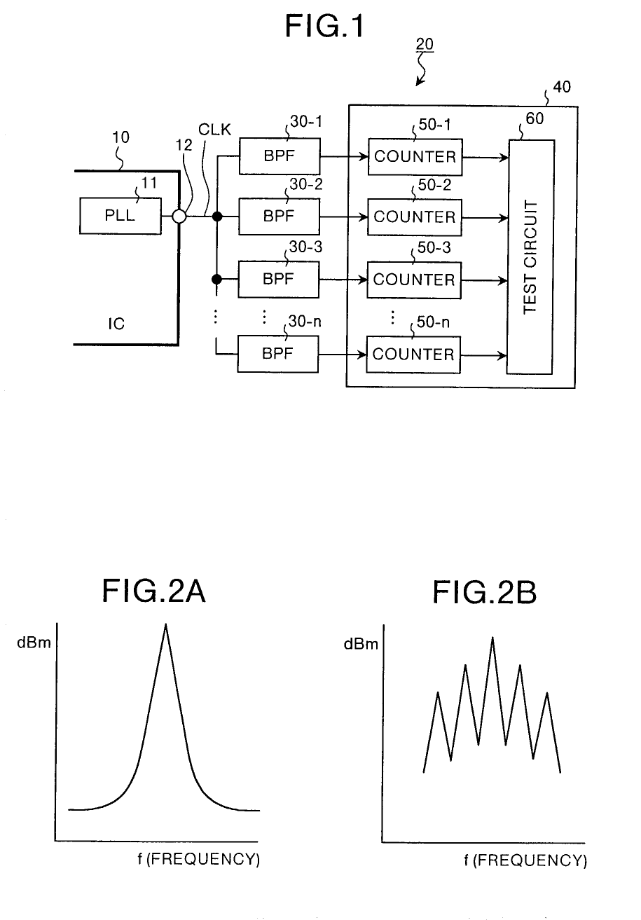

FIG. 1 is a diagram which conceptually shows a configuration of the test apparatus according to the first embodiment of the present invention. As shown in this figure, an IC 10 incorporates a PLL circuit 11 as an oscillation circuit, and it is assumed that a jitter test of the PLL circuit 11 is to be carried out.

As is generally known, the PLL circuit 11 includes a phase comparator, a charge pump, a loop filter, a VCO (voltage controlled oscillator), and a frequency divider which outputs a frequency-multiplied system clock. A clock signal from an external oscillation circuit or an internal reference oscillator is input to the PLL circuit 11. The PLL circuit 11 conducts phase synchronization between the input clock signal and an internally generated clock signal. In addition, the PLL circuit 11 multiplies the frequency of the clock signal subjected to the phase synchronization by a factor in the range of 1 to n to generate a fast system clock signal CLK, and outputs the system clock signal CLK to an internal circuit. The system clock signal CLK output from the PLL circuit 11 is taken out to the outside via an external output terminal 12.

A test apparatus 20 which conducts an inspection on the system clock signal CLK output from the PLL circuit 11 includes a plurality of band pass filters (BPF's) 30-1 to 30-n and a tester 40. The tester 40 incorporates a plurality of counters 50-1 to 50-n and a test circuit 60.

One BPF out of the plurality of BPF's 30-1 to 30-n conducts a band pass operation such that a center frequency equivalent to an oscillation frequency band (hereafter referred to as desired frequency) of the oscillation signal (system clock signal) CLK output from the PLL circuit 11. Other BPF's conduct band pass operations such that center frequencies equivalent to a plurality of different frequencies in the vicinity of the desired frequency band.

FIG. 2A and FIG. 2B show output waveforms obtained when the output of the PLL circuit 11 is measured by using a spectrum analyzer. FIG. 2A shows an output waveform of a good (i.e. non-defective) article. FIG. 2B shows an output waveform of a defective article which includes jitter.

If the PLL circuit 11 is a good article, a spectrum exists only at the desired frequency as shown in FIG. 2A. On the other hand, if the PLL circuit 11 is a defective article, spectra also exist in frequency bands other than the desired frequency due to jitter as shown in FIG. 2B. If the PLL circuit 11 is a good article, therefore, the output of the PLL circuit 11 is passed through only one band pass filter having the desired frequency as its pass communication frequency. If the PLL circuit 11 is a defective article, the output of the PLL circuit 11 is passed through the plurality of band pass filters other than the band pass filter having the desired frequency as its pass communication frequency.

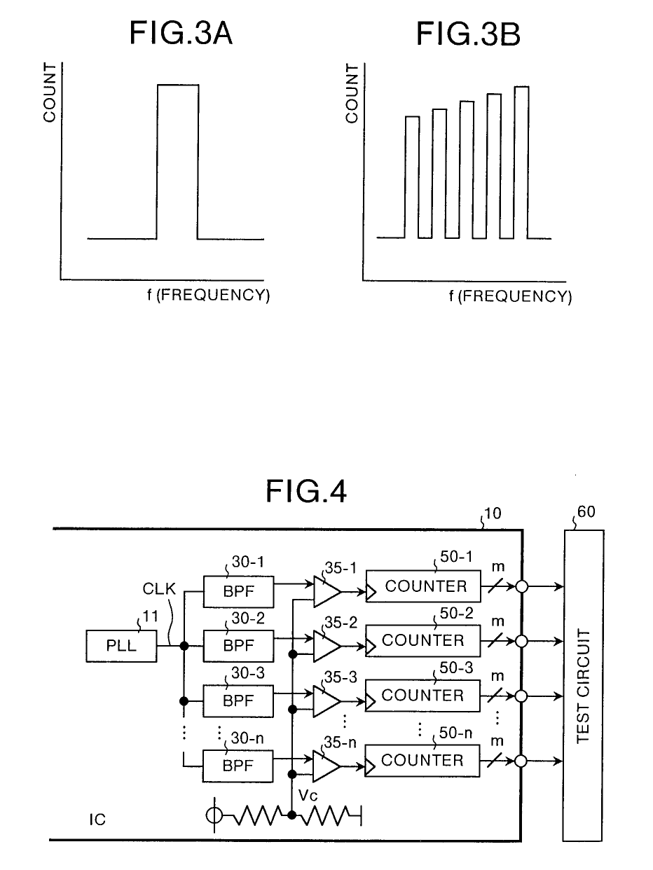

Each counter of the plurality of counters 50-1 to 50-n of the tester 40 counts output of the corresponding BPF. The result of counting are supplied to the test circuit 60. If the PLL circuit 11 is a good article, the output of the PLL circuit 11 is passed through only one band pass filter having the desired frequency as its pass communication frequency. As shown in FIG. 3A, therefore, only the output of the BPF of the desired frequency is counted by one counter. On the other hand, if the PLL circuit 11 is a defective article, the output of the PLL circuit 11 is also passed through band pass filters other than the band pass filter having the desired frequency. As shown in FIG. 3B, therefore, outputs of the plurality of BPF's are counted by a plurality of counters. Accordingly, count outputs are obtained from the plurality of counters.

The test circuit 60 determines whether the PLL circuit 11 under test is a good article or a defective article on the basis of count outputs of the plurality of counters 50-1 to 50-n. In other words, if a count output is obtained from only the counter which counts the desired frequency and the count coincides with the desired frequency, the PLL circuit 11 is judged to be a good article. If counts are output from a plurality of counters inclusive of the counter which counts the desired frequency, the PLL circuit 11 is judged to be a defective article.

Thus, in the first embodiment, the output of the PLL circuit 11 is passed through a plurality of BPF's differing in center frequency, and the PLL test is conducted on the basis of count results of them. As a result, it becomes possible to conduct an inspection of the PLL circuit 11 including jitter characteristics.

In the first embodiment, the plurality of counters 50-1 to 50-n are provided so as to correspond to the plurality of BPF's 30-1 to 30-n. However, it is also possible to select one of the outputs of the plurality of BPF's 30-1 to 30-n by using a switch circuit, input the one output to one counter, and count outputs of the plurality of BPF's 30-1 to 30-n successively by using the one counter.

The second embodiment will now be explained by referring to FIG. 4. In the second embodiment, a plurality of BPF's 30-1 to 30-n and a plurality of counters 50-1 to 50-n are incorporated in an IC 10 together with a PLL circuit 11.

As shown in FIG. 4, outputs of the plurality of BPF's 30-1 to 30-n are input to comparators 35-1 to 35-n, respectively. Each of the comparators 35-1 to 35-n passes only an amplitude of at least a predetermined reference voltage Vc, and thereby removes noise components. Signals passed through the comparators 35-1 to 35-n are counted by the counters 50-1 to 50-n, respectively. A count result having a plurality of bits m of each of the counters 50-1 to 50-n is input from the IC 10 to a test circuit 60 via an external output terminal. In the same way as the first embodiment, the test circuit 60 determines whether the PLL circuit 11 under test is a good article or a defective article on the basis of count outputs of the plurality of counters 50-1 to 50-n.

In the second embodiment, a plurality of BPF's, comparators and counters are incorporated in an IC. Even a tester having no count function can implement a high precision PLL jitter test.

In the second embodiment as well, it is possible to select one of the outputs of the plurality of BPF's 30-1 to 30-n by using a switch circuit, input the one output to one counter, and count outputs of the plurality of BPF's 30-1 to 30-n successively by using the one counter.

The third embodiment of the present invention will now be explained by referring to FIG. 5. In the third embodiment, an oscillation buffer 15 is incorporated in an IC 10 as an oscillation circuit. A jitter test of the oscillation buffer 15 is carried out.

An oscillation circuit including the oscillation buffer 15 includes the oscillation buffer 15 formed of a CMOS inverter and soon, and a feedback circuit. The feedback circuit includes an oscillation vibrator 16 such as a crystal resonator, a feedback resistor (not shown), and a capacitor (not shown). In such an oscillation circuit, a signal input to an input terminal of the oscillation buffer 15 is amplified with an amplification factor which depends upon a gain of the oscillation buffer 15. A resultant amplified signal is output to an output terminal of the oscillation buffer 15.

An oscillation signal output from the oscillation buffer 15 incorporated in the IC 10 is input to a test apparatus 20 via an external terminal. In the same way as the first embodiment, the test apparatus 20 includes a plurality of BPF's 30-1 to 30-n and a tester 40. The tester 40 includes a plurality of counters 50-1 to 50-n and a test circuit 60. Since operations of respective components are the same as those of the first embodiment, explanation of them will be omitted.

Thus, in the third embodiment, the output of the oscillation buffer is passed through a plurality of BPF's differing in center frequency, and a test of the oscillation buffer is conducted on the basis of count results of them. As a result, it becomes possible to conduct an inspection of the oscillation buffer including jitter characteristics.

In the third embodiment, it is possible to select one of the outputs of the plurality of BPF's 30-1 to 30-n by using a switch circuit, input the one output to one counter, and count outputs of the plurality of BPF's 30-1 to 30-n successively by using the one counter.

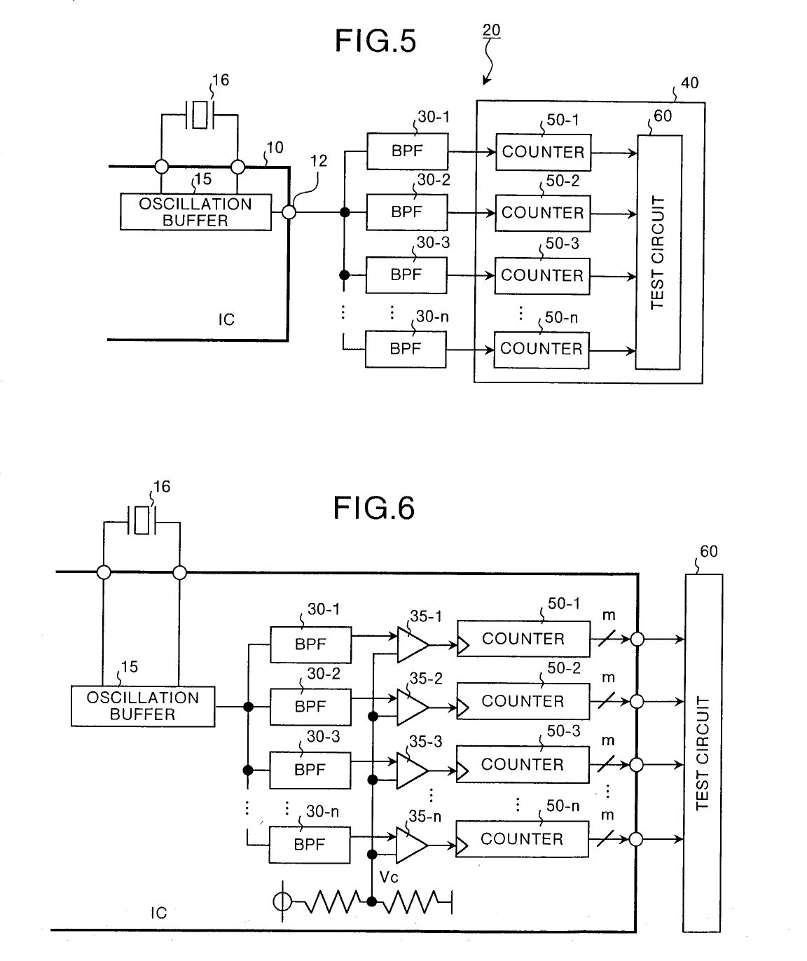

The fourth embodiment of the present invention will now be explained by referring to FIG. 6. In the fourth embodiment as well, an oscillation buffer 15 is incorporated in an IC 10 as an oscillation circuit. A jitter test of the oscillation buffer 15 is carried out. In the fourth embodiment, a plurality of BPF's 30-1 to 30-n, a plurality of comparators 35-1 to 35-n, and a plurality of counters 50-1 to 50-n are incorporated in an IC 10 together with a PLL circuit 11, in the same way as the second embodiment. Since operations of respective components are the same as those of the second embodiment, explanation of them will be omitted.

In the fourth embodiment, the output of the oscillation buffer is passed through a plurality of BPF's differing in center frequency, and a test of the oscillation buffer is conducted on the basis of count results of them. In addition, a plurality of BPF's, comparators, and counters are incorporated in an IC. Even in a test circuit having no count function, therefore, a high precision jitter test of oscillation buffers can be implemented.

In the fourth embodiment, it is possible to select one of the outputs of the plurality of BPF's 30-1 to 30-n by using a switch circuit, input the one output to one counter, and count outputs of the plurality of BPF's 30-1 to 30-n successively by using the one counter.

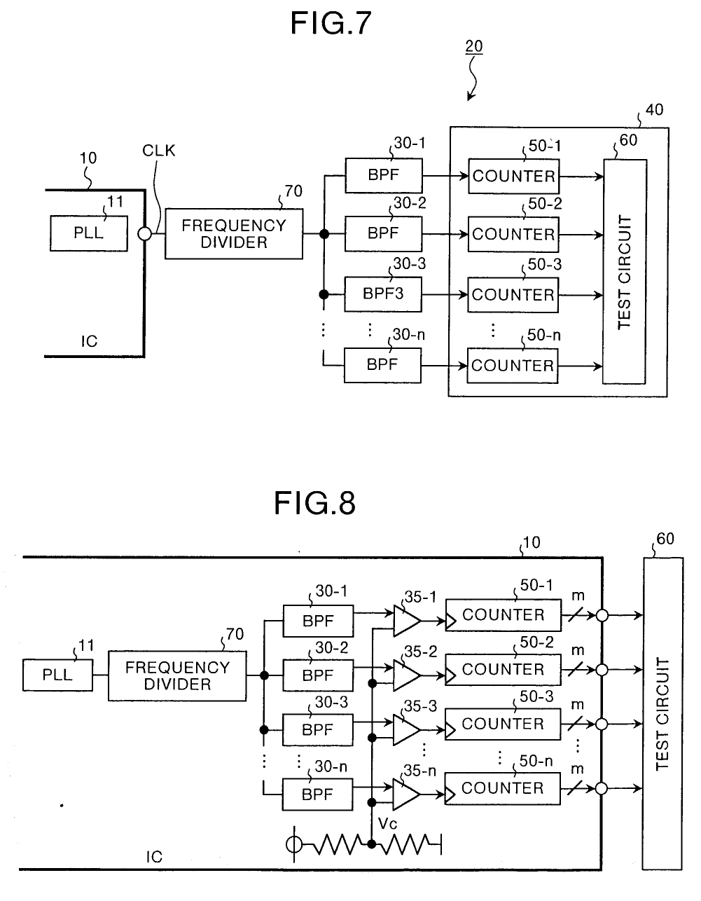

The fifth embodiment of the present invention will now be explained by referring to FIG. 7. In the fifth embodiment, a frequency divider 70 is inserted between the PLL circuit 11 and the BPF's 30-1 to 30-n of the first embodiment shown in FIG. 1. The clock signal CLK output from the PLL circuit 11 is subjected in the frequency divider 70 to frequency division with a factor n. After being thus lowered in frequency, the clock signal CLK is input to the BPF's 30-1 to 30-n. Since operations of other components are the same as those of the first embodiment, explanation of them will be omitted.

Thus, in the fifth embodiment, the frequency of the clock signal CLK output from the PLL circuit 11 is lowered by the frequency divider 70, and a resultant signal is input to the BPF's 30-1 to 30-n. Even if a tester 40 incorporates only counters which cannot count a high frequency, therefore, a jitter test of an oscillation circuit such as a PLL circuit can be implemented.

The sixth embodiment of the present invention will now be explained by referring to FIG. 8. In the sixth embodiment, a frequency divider 70 is inserted between the PLL circuit 11 and the BPF's 30-1 to 30-n of the second embodiment shown in FIG. 2. The clock signal CLK output from the PLL circuit 11 is subjected in the frequency divider 70 to frequency division with a factor n. After being thus lowered in frequency, the clock signal CLK is input to the BPF's 30-1 to 30-n. In other words, the frequency divider 70, the BPF's 30-1 to 30-n, the comparators 35-1 to 35-n, and the counters 50-1 to 50-n are incorporated in the IC 10.

Thus, in the sixth embodiment, the frequency of the clock signal CLK output from the PLL circuit 11 is lowered by the frequency divider 70, and a resultant signal is input to the BPF's 30-1 to 30-n. Even if a tester 40 incorporates only counters which cannot count a high frequency, therefore, a jitter test of the PLL circuit 11 can be implemented. The number of bits of the counters to be incorporated in the IC 10 can be reduced. Even in an IC in which the frequency is high and the input and output pins are insufficient, a jitter test of an oscillation circuit such as the PLL circuit 11 can be implemented.

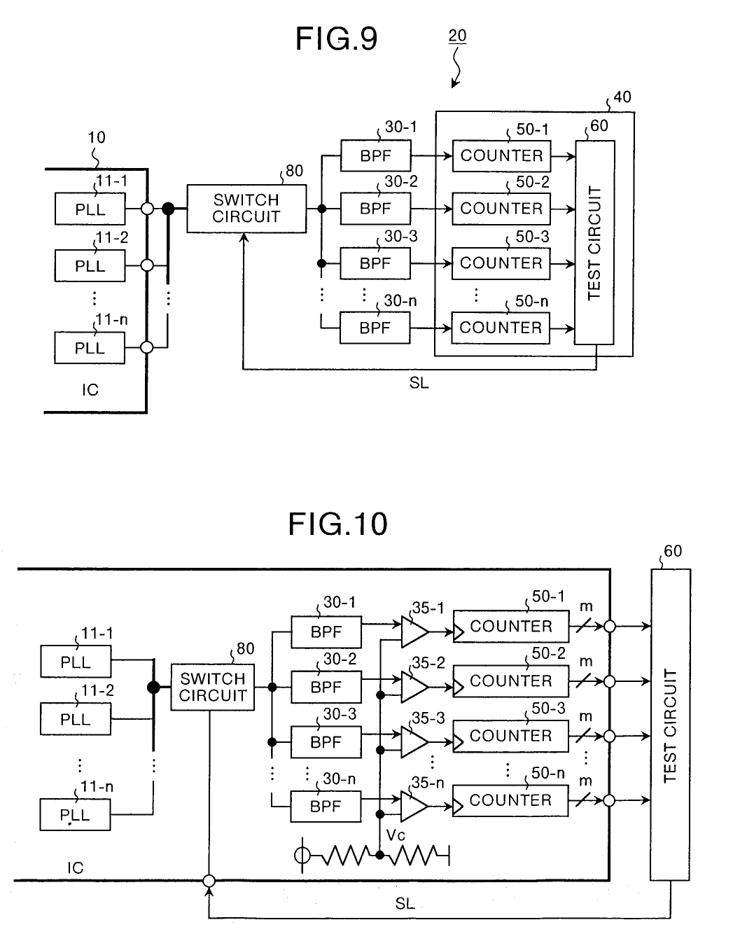

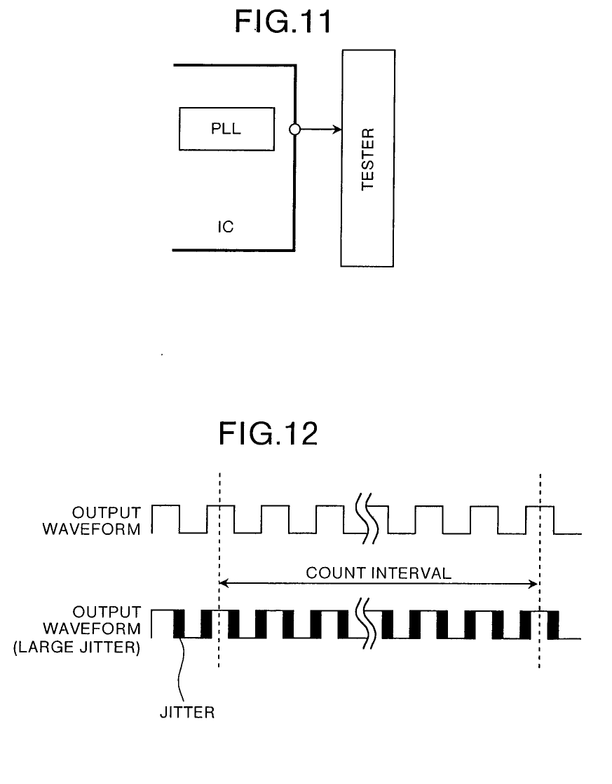

The seventh embodiment of the present invention will now be explained by referring to FIG. 9. In the seventh embodiment, it is supposed that a plurality of oscillation circuits (in this instance, PLL circuits 11-1 to 11-n) are incorporated in an IC 10.

In the seventh embodiment, a switch circuit 80 is added to the components of the first embodiment. The switch circuit 80 is inserted in a stage immediately preceding the plurality of BPF's 30-1 to 30-n. A plurality of clock signals from a plurality of PLL circuits 11-1 to 11-n are input to the switch circuit 80. The switch circuit 80 selects one of the plurality of PLL circuits 11-1 to 11-n according to a switch changeover signal SL supplied from the test circuit 60. One clock signal selected by the switch circuit 80 is input to the plurality of BPF's 30-1 to 30-n. Thus, in the seventh embodiment, outputs of the plurality of PLL circuits 11-1 to 11-n are selected one after another by the switch changeover signal SL supplied from the test circuit 60. The selected output is input to the BPF's 30-1 to 30-n. Since operations of other components are the same as those of the second embodiment, explanation of them will be omitted.

Thus, in the seventh embodiment, the switch circuit 80 is provided to select one of outputs of a plurality of oscillation circuits and input the selected output to the BPF's. Even if a plurality of oscillation circuits are incorporated in an IC, therefore, a jitter test of the oscillation circuits can be implemented without increasing the circuit scale of the tester.

In FIG. 9, it is also possible to insert the frequency divider 70 shown in FIG. 7 between the switch circuit 80 and the BPF's 30-1 to 30-n, conduct frequency division on the output of the PLL circuit selected by the switch circuit 80 in the frequency divider 70, and then input a resultant signal to the BPF's 30-1 to 30-n.

The eighth embodiment of the present invention will now be explained by referring to FIG. 10. In the eighth embodiment, it is supposed that a plurality of oscillation circuits (in this instance, PLL circuits 11-1 to 11-n) are incorporated in an IC 10 in the same way as the seventh embodiment.

In the eighth embodiment as well, outputs of a plurality of PLL circuits 11-1 to 11-n are selected one after another by a switch changeover signal SL supplied from a test circuit 60 provided outside the IC and input to BPF's 30-1 to 30-n, in the same way as the seventh embodiment. In other words, a switch circuit 80, the BPF's 30-1 to 30-n, comparators 35-1 to 35-n, and counters 50-1 to 50-n are incorporated in the IC 10.

In the eighth embodiment, the switch circuit 80, which selects one of outputs of a plurality of oscillation circuits and inputs the selected output to the BPF's, is incorporated in the IC together with the BPF's 30-1 to 30-n, the comparators 35-1 to 35-n, and the counters 50-1 to 50-n. Even if a plurality of oscillation circuits are incorporated in an IC, therefore, a jitter test of the oscillation circuits can be implemented without increasing the circuit scale of the tester. Even in a test circuit having no count function, a high precision jitter test of PLLs can be implemented.

In FIG. 10, it is also possible to insert the frequency divider 70 shown in FIG. 8 between the switch circuit 80 and the BPF's 30-1 to 30-n, conduct frequency devision on the output of the PLL circuit selected by the switch circuit 80 in the frequency divider 70, and then input a resultant signal to the BPF's 30-1 to 30-n.

In the embodiments described above, a PLL and an oscillation buffer are adopted as an oscillation circuit. However, the present invention can be applied to other arbitrary oscillation circuits so long as an oscillation signal is output.

As heretofore explained, according to one aspect of this invention, an output of an oscillation circuit is passed through a plurality of band pass filters having different center frequencies. A test of the oscillation circuit is conducted on the basis of count results of outputs of the band pass filters. Therefore, it becomes possible to simply conduct an inspection of the oscillation circuit inclusive jitter characteristics by using a simple circuit configuration.

Moreover, a PLL is adopted as the oscillation circuit. Therefore, it becomes possible to simply conduct a jitter characteristic test on a PLL incorporated in an IC by using a simple circuit configuration.

Furthermore, an oscillation buffer is adopted as the oscillation circuit. Therefore, it becomes possible to simply conduct a jitter characteristic test on an output of an oscillation buffer incorporated in an IC by using a simple circuit configuration.

Moreover, a plurality of band pass filters and counters are incorporated in an IC together with an oscillation circuit. Even in a tester having no count function, therefore, a high precision jitter test of the oscillation circuit can be implemented.

Furthermore, one of outputs of a plurality of oscillation circuits incorporated in an IC is selected by a switch circuit, and the selected output is input to a plurality of band pass filters. Even if a plurality of oscillation circuits are incorporated in an IC, therefore, a jitter test of the oscillation circuits can be implemented without increasing the circuit scale of the test circuit.

Moreover, a switch circuit, a plurality of band pass filters and counters are incorporated in an IC together with an oscillation circuit. Even in a tester having no count function, therefore, a high precision jitter test of the oscillation circuit can be implemented. In addition, a jitter test of the oscillation circuit can be implemented without increasing the circuit scale of the test circuit.

According to still another aspect of this invention, an oscillation signal of an oscillation circuit is subject to frequency division in a frequency divider. The oscillation signal thus lowered in frequency is then input to a plurality of band pass filters. The oscillation signal subjected to frequency division and passed through the plurality of band pass filters is counted. It is determined whether the oscillation circuit is good or defective on the basis of a result of the count. Even in a tester having only a low count function, therefore, a jitter test of the oscillation circuit can be simply implemented by using a simple circuit configuration.

Moreover, a PLL is adopted as the oscillation circuit. Even in a tester having only a low count function, therefore, it becomes possible to simply conduct a jitter characteristic test on a PLL incorporated in an IC by using a simple circuit configuration.

Furthermore, an oscillation buffer is adopted as the oscillation circuit. Even in a tester having only a low count function, therefore, it becomes possible to simply conduct a jitter characteristic test on an output of an oscillation buffer incorporated in an IC by using a simple circuit configuration.

Moreover, a frequency divider, a plurality of band pass filters and counters are incorporated in an IC together with an oscillation circuit. Even in a tester having only a low count function, therefore, a jitter test of oscillation circuit can simply be realized by a simple circuit configuration and a jitter test of oscillation circuit with a high accuracy can also be realized with a test circuit which does not have a count function.

Furthermore, one of outputs of a plurality of oscillation circuits incorporated in an IC is selected by a switch circuit, and the selected output is input to a frequency divider. Even if a plurality of oscillation circuits are incorporated in an IC, therefore, a jitter test of the oscillation circuits can be implemented without increasing the circuit scale of the test circuit. In addition, even in a tester having only a low count function, therefore, a jitter test of the oscillation circuit can be implemented by using a simple circuit configuration.

Moreover, a switch circuit, a frequency divider, a plurality of band pass filters and counters are incorporated in an IC together with an oscillation circuit. Even if a plurality of oscillation circuits are incorporated in an IC, therefore, a jitter test of the oscillation circuits can be implemented without increasing the circuit scale of the test circuit. In addition, even in a tester having no count function, therefore, a jitter test of oscillation circuit can simply be realized by a simple circuit configuration and a jitter test of oscillation circuit with a high accuracy can also be realized with a test circuit which does not have a count function.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A test apparatus for conducting a jitter test on an oscillation circuit incorporated in an integrated circuit, the test apparatus comprising:
a plurality of band pass filters each of which receives an oscillation signal output by the oscillation circuit, wherein each of the band pass filters has an oscillation frequency band of the oscillation circuit and a plurality of different frequencies located near the oscillation frequency band of the oscillation circuit as pass band center frequencies;
a plurality of counters, one counter corresponding to one of the band pass filters, wherein the counter counts a signal output from the corresponding band pass filter; and
a test circuit which receives the result of the counting by the counters and detects defectiveness of the oscillation circuit based on the received result of the counting.

2. The test apparatus according to claim 1, wherein the oscillation circuit is a phase locked loop.

3. The test apparatus according to claim 1, wherein the oscillation circuit is an oscillation buffer.

4. The test apparatus according to claim 1, wherein the band pass filters and the counters are incorporated in the integrated circuit.

5. The test apparatus according to claim 1, further comprising:
a plurality of the oscillation circuits, wherein the oscillation circuits are incorporated in the integrated circuit; and
a switch circuit which receives a switch changeover signal from the test circuit and oscillation signals output from the oscillation circuits, and selects one oscillation signal from among the oscillation signals to be input into the band pass filters.

6. The test apparatus according to claim 5, wherein the switch circuit, the band pass filters, and the counters are incorporated in the integrated circuit.

7. A test apparatus for conducting a jitter test on an oscillation circuit incorporated in an integrated circuit, the test apparatus comprising:
a frequency divider which receives an oscillation signal output by the oscillation circuit and conducts frequency division on the oscillation signal to produce a frequency-divided oscillation signal;
a plurality of band pass filters each of which receives the frequency-divided oscillation signal output by the frequency divider, wherein each of the band pass filters has an oscillation frequency band of the oscillation circuit subjected to frequency division and a plurality of different frequencies located near the oscillation frequency band of the oscillation circuit subjected to frequency division as pass band center frequencies;
a plurality of counters, one counter corresponding to one of the band pass filters, wherein the counter counts a signal output from the corresponding band pass filter; and
a test circuit which receives the result of the counting by the counters and detects defectiveness of the oscillation circuit based on the received result of the counting.

8. The test apparatus according to claim 7, wherein the oscillation circuit is a phase locked loop.

9. The test apparatus according to claim 7, wherein the oscillation circuit is an oscillation buffer.

10. The test apparatus according to claim 7, wherein the frequency divider, the band pass filters and the counters are incorporated in the integrated circuit.

11. The test apparatus according to claim 7, further comprising:
a plurality of the oscillation circuits, wherein the oscillation circuits are incorporated in the integrated circuit; and
a switch circuit which receives a switch changeover signal from the test circuit and oscillation signals output from the oscillation circuits, and selects one oscillation signal from among the oscillation signals to be input into the frequency divider.

12. The test apparatus according to claim 11, wherein the switch circuit, the frequency divider, the band pass filters, and the counters are incorporated in the integrated circuit.
